(19) United States
(12) Patent Application Publication
(10) Pub. No.: US 2007/0023757 A1
(43) Pub. Date: Feb. 1, 2007

(54) THIN-FILM TRANSISTOR, METHOD FOR MANUFACTURING THIN-FILM TRANSISTOR, AND DISPLAY USING THIN-FILM TRANSISTOR

(76) Inventors: Yoshiaki Nakazaki, Saitama-shi (JP); Genshiro Kawachi, Chiba-shi (JP); Terunori Warabisako, Nishitama-gun (JP); Masakiyo Matsumura, Kamakura-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/428,496

(22) Filed: Jul. 3, 2006

(30) Foreign Application Priority Data
Jul. 5, 2005 (JP) 2005-196858

(51) Int. Cl. H01L 29/76

(52) U.S. Cl. 257/66

(57) ABSTRACT

The present invention provides a thin-film transistor having a higher mobility for electrons or holes, a method for manufacturing the thin-film transistor, and a display using the thin-film transistor. Thus, the present invention provides a thin-film transistor having a source region, a channel region, and a drain region in a semiconductor thin film having a crystallization region with a crystal grown in a horizontal direction, the thin-film transistor having a gate insulating film and a gate electrode over the channel region, wherein a drain edge of the drain region which is adjacent to the channel region is formed in the vicinity of a crystal growth end position.

### CROSS-REFERENCE TO RELATED APPLICATIONS

This application is based upon and claims the benefit of priority from prior Japanese Patent Application No. 2005-196858, filed Jul. 5, 2005, the entire contents of which are incorporated herein by reference.

### BACKGROUND OF THE INVENTION

1. Field of the Invention

The present invention relates to a thin-film transistor, a method for manufacturing a thin-film transistor, and a display using the thin-film transistor.

2. Description of the Related Art

Amorphous silicon thin films and polysilicon thin films have been used as semiconductor thin films used to form, for example, thin-film transistors (TFTs) serving as switching elements that control voltages applied to pixels in a liquid crystal display (LCD) or thin-film transistors for a control circuit for the liquid crystal display.

In TFTs using polysilicon thin films as semiconductor thin films, electrons or holes migrating through a channel region generally have a higher mobility than in TFTs using amorphous silicon thin films as semiconductor thin films. Accordingly, the transistors using polysilicon thin films have higher switching speeds and can thus operate faster, than the transistors using amorphous silicon thin films. This enables TFTs to be used to form an LCD pixel selection circuit and a peripheral drive circuit to be formed on the same substrate on which pixel control thin-film transistors are formed; the peripheral drive circuit drives LCD. Further, the design margin of other parts can advantageously be increased. A cost and size reduction and an increased definition can also be achieved by incorporating the peripheral drive circuit such as a driver circuit or DAC into a display section including the pixel control thin-film transistors.

The present applicant has developed an industrialization technique for stably manufacturing a large-grain-size crystallization region in a non-single-crystal semiconductor thin film formed on an insulating substrate. As a method for forming a large-grain-size crystallization region, crystallization methods have been proposed in, for example, “Method for Forming Giant Crystal Grain Si Film Using Excimer Laser”, Masakiyo MATSUMURA, Surface Science, Vol. 21, No. 5, pp. 278 to 287, 2000, and “Method for Forming Giant Crystal Grain Si Film Using Excimer Laser Light Irradiation”, Masakiyo MATSUMURA, Applied Physics, Vol. 71, No. 5, pp. 543 to 547, 2000. Successful industrialization of a large-grain-size crystallization region enables not only the liquid crystal display section and switching transistors for the pixels but also a memory circuit such as DRAM or SRAM, an arithmetic and logic circuit, or the like to be formed on a glass substrate. This enables a reduction in the amount of power required by the entire liquid crystal display and its size.

The present inventor et al. have developed a manufacture technique for forming higher-performance TFTs that offer practical, optimum transistor characteristics. For example, a single-crystal silicon having a crystal with a large grain size grown by executing a thermal treatment on an amorphous silicon thin film has a surface different from that of a single-crystal silicon wafer formed by slicing a single-crystal rod formed by a normal lift-off method. Specifically, the former single-crystal silicon has a thin film that is not microscopically flat and has a complicated grain boundary generated during crystal growth. It has thus been found that desired transistor characteristics are not obtained simply by forming TFT at an arbitrary portion in the crystallization region.

### BRIEF SUMMARY OF THE INVENTION

An object of the present invention is to provide a thin-film transistor structure offering optimum transistor characteristics, a method for manufacturing the thin-film transistor, and a display using the thin-film transistor.

A thin-film transistor described in an embodiment according to the present invention has a source region, a channel region, and a drain region in a semiconductor thin film having a crystallization region with crystal growth in a horizontal direction, has a gate insulating film and a gate electrode over the channel region, and is characterized in that a channel region side edge of the drain or source region is provided in the crystallization region except for a vicinity of a crystal growth start position or a vertical direction growth start position.

A thin-film transistor described in an embodiment according to the present invention has a source region, a channel region, and a drain region in a semiconductor thin film having a crystallization region with a crystal grown in a horizontal direction, has a gate insulating film and a gate electrode over the channel region, and is characterized in that a channel region side edge of the drain or source region is provided in the crystallization region at least 1.0 μm away from a vertical direction growth start position.

A thin-film transistor described in an embodiment according to the present invention has a source region, a channel region, and a drain region in a semiconductor thin film having a crystallization region with a crystal grown in a horizontal direction, the crystallization region having an inclined surface which rises toward a crystal growth end. The thin-film transistor has a gate insulating film and a gate electrode over the channel region, and is characterized in that a channel region side edge of the drain or source region is provided in the crystallization region at least 1.0 μm away from a vertical direction growth start position.

The crystallization region in the thin-film transistor is a single-crystal region formed by irradiating the non-single-crystal semiconductor film with pulse laser light. In this case, the pulse laser light is made via a homogenizer and a phase shifter to have a reverse peak-like light intensity distribution.

A method for manufacturing a thin-film transistor according to an embodiment of the present invention is characterized by comprising a step of irradiating a non-single-crystal semiconductor film with laser light having a reverse peak-like light intensity distribution to crystallize an irradiated region to form a crystallization region, and a step of forming a thin-film transistor so that a side edge of the drain or source region which is adjacent to the channel region is positioned in the crystallization region at least 1.0 μm away from a crystal growth start position or a vertical growth start position in the crystallization region.

The thin-film transistor having the above configuration or manufactured as described above can be formed in the crystallization region so as to have higher electron or hole mobility than conventional TFTs.

A display according to an embodiment of the present invention has the above thin-film transistor provided in a peripheral circuit section which includes a signal and scan line drive circuits and which needs to operate at high speed. The use of the above thin-film transistor enables the implementation of a system display in which active elements such as a peripheral circuit section and a memory circuit section are formed on the same substrate.

### BRIEF DESCRIPTION OF THE SEVERAL VIEWS OF THE DRAWING

FIG. 1 is a partly cutaway sectional view illustrating the configuration of a thin-film transistor of the present invention;

FIG. 2 is a process diagram illustrating a process of manufacturing TFT shown in FIG. 1, in order of the steps;

FIG. 3 is a characteristic diagram showing a mobility characteristic and an off current characteristic vs. a drain edge position in the n-channel type thin-film transistor shown in FIG. 1;

FIG. 4 is a characteristic diagram showing a Vth characteristic and an S value characteristic vs. the drain edge position in the n-channel type thin-film transistor shown in FIG. 1;

FIG. 5 is a characteristic diagram showing a mobility characteristic and an off current characteristic vs. a drain edge position in a p-channel type thin-film transistor according to an embodiment different from that shown in FIG. 1;

FIG. 6 is a characteristic diagram showing a Vth characteristic and an S value characteristic vs. the drain edge position in the p-channel type thin-film transistor according to the embodiment different from that shown in FIG. 1;

FIG. 7 is a diagram of configuration of a crystallization apparatus illustrating the crystallization process shown in FIG. 2;

FIG. 8 is a diagram illustrating an illuminating optical system shown in FIG. 7, in further detail;

FIG. 9 is a diagram illustrating the structure of a substrate in which crystallization is carried out by the crystallization process shown in FIG. 2 and the shape of a crystallized semiconductor thin film;

FIG. 10 is a sectional view illustrating an example of the TFT manufacture process shown in FIG. 2, in order of the steps;

FIG. 11 is a sectional view illustrating a postprocess of the TFT manufacture process shown in FIG. 10, in order of the steps;

FIG. 12 is a sectional photograph of FIG. 13;

FIG. 13 is a photograph of FIG. 12 as viewed from above;

FIG. 14 is a characteristic diagram showing a comparison of mobility characteristics of a large number of TFTs obtained by the processes shown in FIGS. 6 and 7;

FIG. 15 is a circuit diagram illustrating an example to which the thin-film transistor in FIG. 1 is applied to a liquid crystal display;

FIG. 16 is a characteristic diagram of an n-channel type TFT showing that for thin-film transistors different from the one shown in FIG. 3, the mobility characteristic of the thin-film transistor depends on its drain edge formation position;

FIG. 17 is a characteristic diagram of a p-channel type TFT showing that for thin-film transistors different from the one shown in FIG. 5, the mobility characteristic of the thin-film transistor depends on its drain edge formation position;

FIG. 18 is a characteristic diagram showing a drain current vs. a gate voltage in thin-film transistors different from the one shown in FIG. 1 in which the drain edge formation position is varied in the formation of the thin-film transistor;

FIG. 19 is a characteristic diagram of another embodiment showing a Vth characteristic and an S value characteristic vs. the drain edge position in the n-channel type thin-film transistor shown in FIG. 1; and

FIG. 20 is a characteristic diagram of another embodiment showing a comparison of mobility characteristics of a large number of TFTs obtained by the processes shown in FIGS. 6 and 7.

### DETAILED DESCRIPTION OF THE PREFERRED EMBODIMENT

An embodiment of the present invention will be described below with reference to the drawings. The description below relates to one embodiment of the present invention and is intended to illustrate the general principle of the present invention. Accordingly, the description is not intended to limit the present invention to this embodiment section or to the configurations specifically shown in the accompanying drawings. In the following detailed description and the drawings, similar elements are denoted by similar reference numerals.

The present inventor has developed and applied for a patent on a technique for manufacturing TFT by aligning a drain or source end with the vicinity of a crystal growth end position, as means for providing optimum transistor characteristics for a crystallization region with a crystal grown in a horizontal direction. To form as many TFTs as possible in a large-grain-size crystallization region with a crystal grown in the horizontal direction, the present inventor wholeheartedly studied the transistor characteristics of the crystallization region in the vicinity of a crystal growth start position. As a result, the present inventor has found a region offering the optimum transistor characteristics.

In the embodiment described below, TFT is formed in a crystallization region with a crystal grown in the horizontal direction. In this TFT, the channel region side edge of a drain or source region is formed in the crystallization region at a position that does not correspond to the vicinity of a crystal growth start position or a vertical growth start position. For example, TFT is formed in the crystallization region at least 1.0 μm away from the crystal growth start position or a vertical growth start position. This method enables the optimum characteristics to be offered.

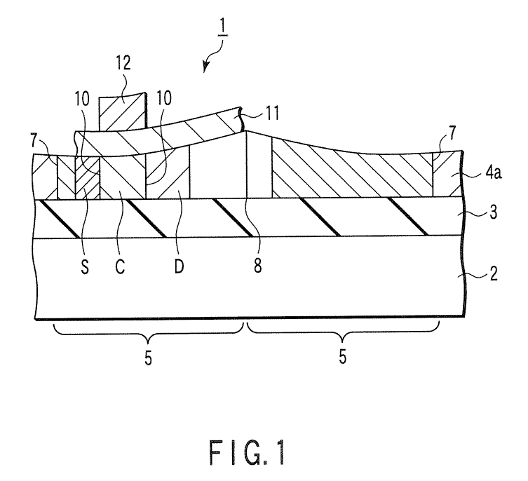

With reference to FIG. 1, description will be given of an embodiment of a thin-film transistor according to the present invention. FIG. 1 is an enlarged sectional view showing a region in which a thin-film transistor is formed. This embodiment has the following characteristics.

In a laser light irradiated region of a non-single-crystal semiconductor layer, a crystallization region 5 is formed by crystal growth in the horizontal direction under predetermined growth conditions. Specifically, the crystallization region 5 (7-S-C-D-8) is shaped so that crystal growth progresses in the horizontal direction from a crystal growth start position 7, with the crystal rising maximally at a crystal growth end position 8. A non-single-crystal semiconductor layer, for example, an amorphous silicon film, is irradiated with light to cause crystal growth in the crystallization region 5 in the horizontal direction to crystallize the crystallization region 5. The crystallization region 5 thus normally has an inclined surface having a film thickness increasing from the crystal growth start position 7 to the crystal growth end position 8. In this crystallization region 5, an electron or hole mobility (μmax) increases in a crystal growth direction and significantly in the vicinity of a crystal growth end portion.

The present inventor has found that a large number of fine crystal grains are distributed in the vicinity of the crystal growth start position 7. Accordingly, it is not desirable that TFT be formed by aligning its drain edge with the vicinity of the crystal growth start position 7. In other words, forming TFT by aligning its drain edge with the vicinity of the crystal growth start position 7 may make undesirable transistor characteristics, for example, a mobility characteristic, a Vth characteristic, and an off current characteristic. TFT according to the present embodiment effectively utilizes the above mobility increase region.

The crystallization region formed by crystallizing the light irradiated region of the non-single-crystal semiconductor layer in the horizontal direction is a semiconductor thin film having an inclined surface which results from crystal growth progressing in the horizontal direction from the crystal growth start position 7 and which rises toward the crystal growth end position 8. Although the reason is not clear, the laser has a significant fluence at an edge of the raised portion, where the terminal of the crystallization region 5 having grown from the right side of FIG. 1 collides against the terminal of the crystallization region 5 having grown from the left side of FIG. 1. This results in a high film stress and abrasion in this region, thus degrading characteristics such as mobility. Thus, the channel region side edge of the drain or source region is desirably located in the crystallization region at a position that does not correspond to the vicinity of the crystal growth start position 7.

Moreover, the crystallization region with the non-single-crystal semiconductor layer crystallized in the horizontal direction is a semiconductor thin film having an inclined surface with a film thickness monotonously increasing in the horizontal direction from the crystal growth start position. At the crystal growth end position, the channel region side edge of the drain or source region is located in the vicinity of peak of the inclined surface with the monotonously increasing film thickness. The non-single-crystal semiconductor film is, for example, a polycrystal film such as Si or an amorphous film.

Now, with reference to FIG. 1, description will be given of an example of specific configuration of TFT driving a liquid crystal display. TFT 1 in FIG. 1 has a top gate type thin-film transistor structure. A substrate 2 is an insulating substrate but may be a semiconductor or metal substrate having an insulating film formed on its surface. An insulating film, for example, a silicon oxide film 3, is provided on the insulating substrate, for example, the glass substrate 2. The silicon oxide film 3 is, for example, a CVD film or thermal oxide film and has a thickness of for example, 1 μm.

To form a crystallization region, a non-single-crystal semiconductor film, for example, an amorphous silicon film 4, is provided on the entire silicon oxide film 3 (not shown). The amorphous silicon film 4 has a thickness of 30 to 300 nm, more specifically, for example, 200 nm. The amorphous silicon film is deposited by, for example, plasma CVD.

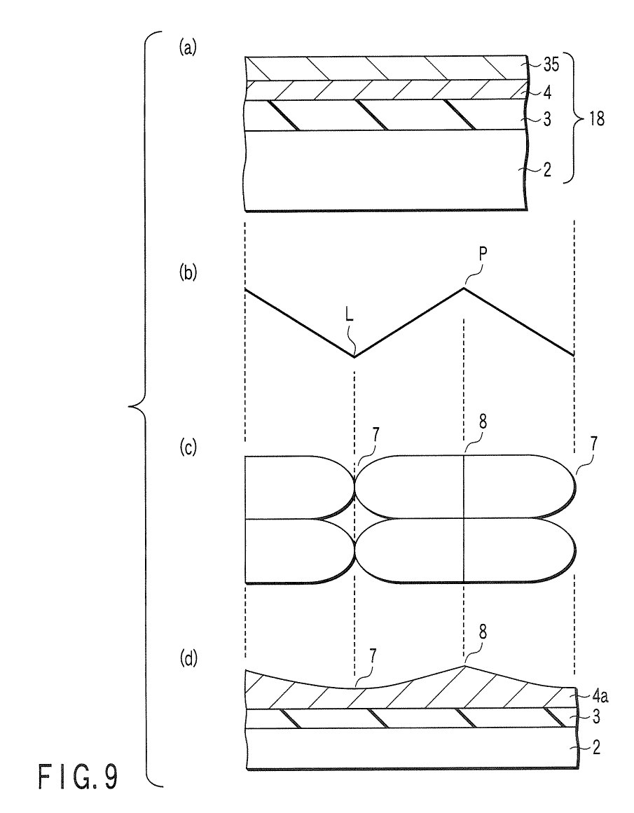

The entire amorphous silicon film 4 or its predetermined region is irradiated with laser light to form a crystallization region 5 shown in FIG. 1. The crystallization region 5 has a light intensity distribution like a reverse peak pattern as shown at L in FIG. 9(b). The crystallization region 5 is formed by crystallization based on irradiation with laser a light beam having energy sufficient to melt the amorphous silicon film 4, for example, KrF excimer laser light.

In the crystallization region 5 crystallized by laser light having a plurality of light intensity distributions like reverse peak patterns, crystal growth progresses with the film thickness sequentially increasing in the horizontal direction from the crystal growth start position 7. The crystallization region 5 has a sectional shape corresponding to the crystallized and raised single-crystal silicon film, in the vicinity of the crystal growth end position 8. In the crystallization region 5 crystallized by laser light having a plurality of light intensity distributions like reverse peak patterns, the crystallized crystal growth end positions 8 collide against each other at the adjacent positive peak portions. This results in an angled sectional shape corresponding to the raised silicon film. In the present specification, a semiconductor film with its predetermined position crystallized is defined as a semiconductor thin film 4a. The length between the crystal growth start position 7 and the crystal growth end position 8 is determined by the pulse width of the reverse peak-like light intensity distribution in FIG. 9(b).

In the embodiment shown in FIG. 1, TFT 1 is formed by placing the drain or source edge of a channel region C of TFT 1 in the crystallization region 5 at a position that does not correspond to the vicinity of the crystal growth start position 7. For example, TFT 1 is formed by placing the drain edge 10 (side end 10) of the channel region C of TFT 1 in the crystallization region at least 1.0 μm away from the crystal growth start position 7. The channel region C is formed adjacent to the drain region D, with the source region S adjacent to the channel region C.

A gate insulating film 11, for example, a silicon oxide film, is provided on the channel region C so as to align with it. The silicon oxide film may be an oxide film formed by a direct-oxidation low-temperature process based on microwave heating CVD at 300 to 400° C., for example, 350° C.

A gate electrode 12 is provided on the gate insulating film 11 so as to align with the channel region C. TFT 1 is thus manufactured. In the present specification, TFT is an element having a TFT structure and may be used not only as a transistor but also for a memory, a capacitor, or a resistor.

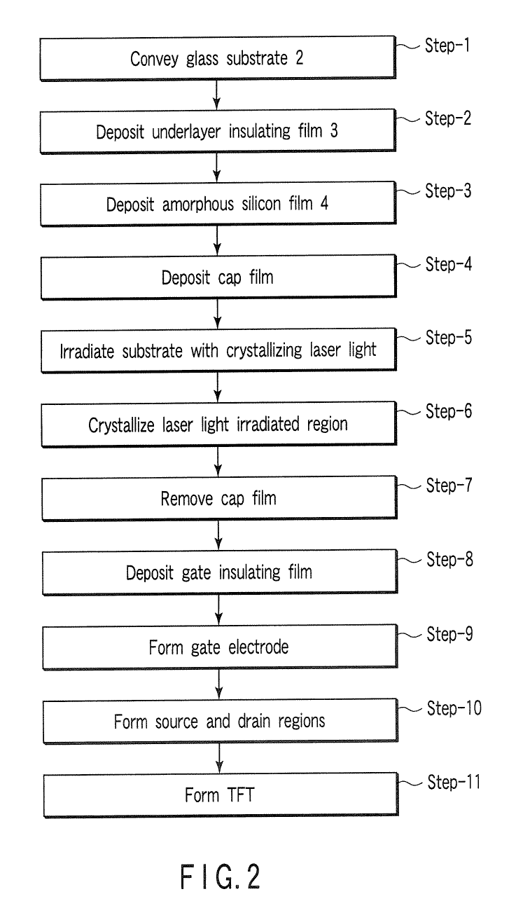

Now, with reference to the process diagram in FIG. 2, description will be given of an example of a method for manufacturing TFT 1. The same components as those in FIG. 1 are denoted by the same reference numerals. Their detailed description is omitted to avoid duplication.

First, a crystallizing substrate is manufactured. For example, a quartz substrate or a glass substrate 2 consisting of no alkali glass is conveyed to a plasma CVD apparatus. The glass substrate 2 is placed and installed at a predetermined position in the plasma CVD apparatus (step-1). An underlayer insulating film, for example, a silicon oxide film 3, is grown in a vapor phase by plasma CVD (step-2). The plasma CVD can be carried out, for example, at a substrate temperature of 500° C. and a deposition time of 40 minutes. Then, a non-single-crystal semiconductor film consisting of amorphous silicon or polycrystal silicon to be crystallized is grown in a vapor phase by plasma CVD (step-3); the non-single-crystal semiconductor film is an amorphous silicon film 4 of film thickness 30 to 300 nm (for example, about 200 nm).

The amorphous silicon film 4 is deposited on the silicon oxide film 3 by, for example, LP-CVD (Lower Pressure CVD). The amorphous silicon film 4 (a-Si) has a thickness of for example, 200 nm. The LP-CVD process is executed, for example, in an Si₂H₆ atmosphere under conditions including a flow rate of 150 sccm, a pressure of 8 Pa, a substrate temperature of 450°° C., and a deposition time of 35 minutes. In this case, the LP-CVD process is used, but instead, for example, a PE-CVD (low-temperature plasma CVD) process may be used.

The non-single-crystal semiconductor thin film is not limited to the amorphous silicon film 4 (Si). For example, a thin film such as Ge or SiGe may be used. Further, the deposition of the non-single-crystal semiconductor thin film is not limited to the CVD process. For example, the deposition may be carried out using a sputtering apparatus.

Then, a cap film through which incident light can be transmitted, for example, a silicon oxide film is deposited on the amorphous silicon film 4 to a film thickness of 10 to 100 nm, for example, 10 nm, by plasma CVD. The cap film is effective in forming a large-grain-size crystallization region. The silicon oxide film is deposited on the amorphous silicon film 4 at a substrate temperature of 500°° C. and a deposition time of 10 minutes by, for example, the LP-CVD process. The cap film consists of an insulating film and exerts a heat storage effect. The cap film reduces the rate of a decrease in the temperature of the non-single-crystal semiconductor thin film 2 when crystallization is carried out using laser light in the subsequent step. A crystallizing cap film is thus manufactured (step-4).

Crystallizing steps 5 and 6 are then executed. The crystallizing substrate is located and installed at a predetermined position in a crystallization apparatus. A crystallization position in the crystallizing substrate conveyed to the crystallization apparatus is irradiated with pulse-like excimer laser light having a light intensity distribution like a reverse peak pattern as shown in FIG. 9(b). The irradiated region is heated to melt the non-single-crystal semiconductor thin film (step-5).

This temperature distribution causes heat to be stored in the cap film. Blocking the excimer laser light lowers the temperature while maintaining a temperature gradient corresponding to a light intensity distribution such as the one shown in FIG. 9(b). With this temperature decrease process, the temperature lowers slowly owing to the heat storage effect of the cap film. Thus, crystal growth occurs along the temperature gradient to form a large-grain-size crystallization region (step-6).

The excimer laser light may be, for example, KrF excimer laser light and may have an energy density of for example, 350 mJ/cm². Positional information for crystallization is pre-stored in a computer. The following process is automatically executed under the control of the computer: the substrate is sequentially moved to and placed at the crystallization position in the crystallizing substrate, and is irradiated with laser light for crystallization to finish the crystallization steps 5 and 6.

The crystallization steps 5 and 6 use a phase modulation excimer laser crystallization method described later in detail. The surface of the cap film is irradiated with excimer laser light having a reverse peak-like light intensity distribution R (see FIG. 9(b)). The pulse laser light irradiation melts that region of the amorphous silicon film 4 which has been irradiated with laser light. Blockage of the pulse laser light lowers the temperature of the melted region. A solidification position having reached a solidifying point moves in a horizontal direction. Crystal growth thus occurs to form a crystallization region 5.

In the crystallization region 5, crystal growth progresses in the horizontal direction from the crystal growth start position 7 to the crystal growth end position 8 as shown in FIG. 1. The width of the crystal is, for example, 2.5 μm. As a result, the amorphous silicon film 4 is converted into a partly or entirely crystallized semiconductor thin film 4a. Pulse laser light irradiation may be carried out once or a number of times. Alternatively, pulse laser light irradiation may be combined with flash lamp light irradiation.

The crystallization region 5 thus formed is normally shaped so that crystal growth progresses in the horizontal direction from the crystal growth start position 7, with the crystal rising toward the crystal growth end position 8, as shown in FIG. 1.

Then, to form TFT 1 in the large-grain-size crystallization region, the silicon oxide film is removed from the deposited cap film (step-7). The silicon oxide film can be removed by a dry etching process. For example, BCl₃ or CH₄ may be used as an etching gas for the dry etching process.

A TFT manufacturing process is then executed using the glass substrate 2 on which the crystallization process has been finished. The present embodiment is characterized in that TFT is formed at a predetermined position in the crystallization region crystallized through above process. TFT is formed so that the channel region side edge of its drain or source region is placed in the crystallization region at least 1.0 μm away from the crystal growth start position or vertical growth start position in the crystallization region.

In the present specification, the “crystal growth start position” or “vertical growth start position” is a position in a crystallized single-crystal region where crystal growth starts as shown in FIG. 9(c). In other words, the crystal growth start position” 7 is a growth start position in a single-crystal region which does not correspond to a fine crystal grain part which is always generated in a crystal growth start part and in which fine crystal grains gather. The “channel region side end” of the drain or source region of TFT is the boundary position between the channel region and the drain or source region that is in contact with the channel region.

First, the glass substrate 2 is conveyed to a predetermined position in a plasma CVD apparatus and placed and installed at that position. A silicon oxide film is deposited, by plasma CVD, on the surface of the crystallized semiconductor thin film exposed from the conveyed substrate, in order to form a gate insulating film 11 (step-8).

Then, the glass substrate 2 on which the gate insulating film 11 has been formed is conveyed to a sputtering apparatus that deposits a conductor film forming a gate electrode. Aluminum (Al) is subsequently deposited as a gate electrode (step-9). The substrate is then conveyed to a plasma etching apparatus, where it is subjected to plasma etching to form a gate electrode 12 while leaving only predetermined parts (step-9).

The gate electrode 12 formed is used as a mask to implant a high concentration of impurity ions into the crystallization region in order to form a source and drain regions. The impurity ions are, for example, phosphorous ions for an N-channel transistor and boron ions for a P-channel transistor. An anneal process (for example, at 600°° C. for one hour) is subsequently executed in a nitrogen atmosphere to activate the impurities. A source region S and a drain region D are thus formed in the crystallization region as shown in FIG. 1. This results in a channel region C between the source region S and the drain region D in which carriers migrate (step-10).

An interlayer insulating layer (not shown) is formed on the gate insulating layer 11 and gate electrode 12. Contact holes (not shown) are then formed in the interlayer insulating layer to connect a source and drain electrodes to the source and drain regions S and D, respectively.

Then, a metal layer constituting a gate electrode, a source, and a drain electrode, for example, aluminum, is filled into the contact holes and deposited on the interlayer insulating layer (not shown). The metal layer deposited on the interlayer insulating layer is etched to a predetermined pattern using a photolithography technique. This forms a source and drain electrodes to manufacture an n-channel type thin-film transistor (step-11). TFT 1 has a gate length of for example, 1 μm.

As is apparent from the above manufacture process, TFT is formed so that the side edge of the source region S or drain region D which is adjacent to the channel region C is placed in the crystallization region at a position that does not correspond to the crystal growth start position 7. Accordingly, this position is determined by the gate electrode 12, acting as an ion implantation mask. The gate electrode 12 is thus placed and installed in a part of the crystallization region which is away from the crystal growth start position 7.

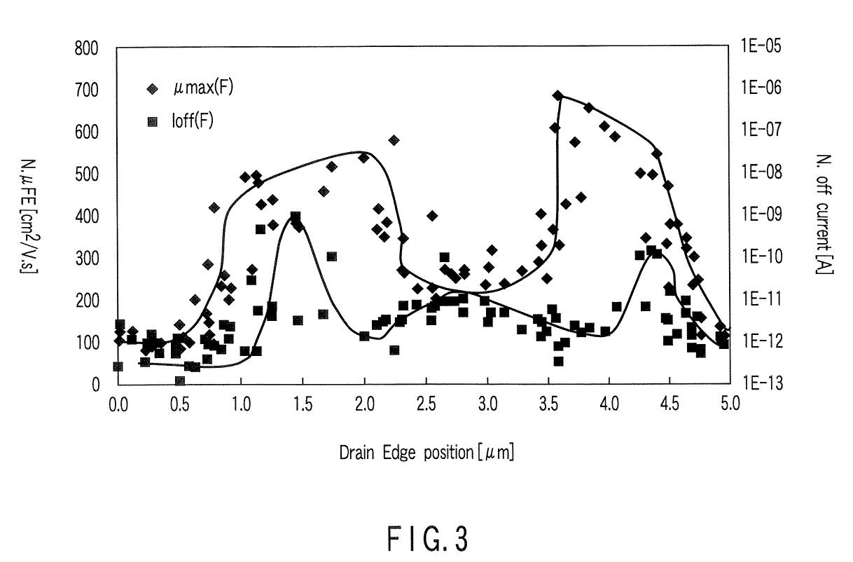

With reference to FIGS. 3 to 6, description will be given of measurements of transistor characteristics of TFT thus manufactured.

FIG. 3 is a characteristic curve diagram showing the relationship between both mobility μ_{FE} [cm²/Vs] and off current [A] and the position of the drain edge in n-channel TFTs 1 observed when each TFT 1 is formed in the crystallization region 5 as described above. FIG. 3 shows the mobility and off current characteristic, where a source-drain electrode voltage Vds=0.1 V and a source-gate electrode voltage Vgs=−5 V.

Mobility μmax Characteristic

The characteristic curve diagram shows that an appropriate mobility characteristic is offered by n-channel type TFTs 1 manufactured so that the drain edge is formed (in the crystallization region) about 1.7 to 2.7 μm or about 4.0 to 5.1 μm away from the crystal growth start position 7. An inappropriate mobility characteristic is offered by n-channel type TFTs 1 manufactured so that the drain edge is formed (in the crystallization region) within 1.7 μm from the crystal growth start position 7 or about 2.9 to 3.7 μm away from the crystal growth start position 7.

Another embodiment shows that an appropriate mobility characteristic is offered by n-channel type TFTs 1 manufactured so that the drain edge is formed (in the crystallization region) about 0.8 to 2.2 μm or about 3.6 to 4.5 μm away from the crystal growth start position 7. An inappropriate mobility characteristic is offered by n-channel type TFTs 1 manufactured so that the drain edge is formed (in the crystallization region) within about 0.7 μm from the crystal growth start position 7 or about 2.3 to 3.6 μm away from the crystal growth start position 7.

Off-current Ioff Characteristic

A larger off current, that is, an inappropriate off current characteristic, is offered by n-channel type TFTs I manufactured so that the drain edge is formed (in the crystallization region) about 1.7 to 2.4 μm or about 4.1 to 4.9 μm away from the crystal growth start position 7. On the other hand, a smaller off current, that is, an appropriate off current characteristic, is offered by n-channel type TFTs 1 manufactured so that the drain edge is formed (in the crystallization region) within about 0.7 μm from the crystal growth start position 7, or about 3.0 to 3.8 μm or about 4.6 to 5.0 μm away from the crystal growth start position 7.

In another embodiment, larger off current, that is, an inappropriate off current characteristic, is offered by n-channel type TFTs 1 manufactured so that the drain edge is formed (in the crystallization region) about 1.2 to 1.7 μm or about 4.1 to 4.8 μm away from the crystal growth start position 7. On the other hand, a smaller off current, that is, an appropriate off current characteristic, is offered by n-channel type TFTs 1 manufactured so that the drain edge is formed (in the crystallization region) within about 1.2 μm from the crystal growth start position 7, or about 2.0 to 4.0 μm or 4.7 to 5.0 μm away from the crystal growth start position 7.

Characteristic of the Mobility and Off-Current Characteristic

An appropriate mobility and off current characteristics are offered by TFTs 1 manufactured so that the drain edge is formed (in the crystallization region) about 0.8 to 1.3 μm, about 1.8 to 2.3 μm, or about 3.6 to 4.2 μm away from the crystal growth start position 7. However, an inappropriate mobility and off current characteristics are offered by TFTs 1 manufactured so that the drain edge is formed (in the crystallization region) within about 0.8 μm from the crystal growth start position 7, or about 1.3 to 1.7 μm, about 2.3 to 3.6 μm, or about 4.2 to 5.0 μm away from the crystal growth start position 7; these regions are difficult to utilize.

In another embodiment, an appropriate mobility and off current characteristics are offered by TFTs 1 manufactured so that the drain edge is formed (in the crystallization region) about 0.8 to 1.2 μm, about 1.8 to 2.2 μm, or about 3.6 to 4.2 μm away from the crystal growth start position 7. However, an inappropriate mobility and off current characteristics are offered by TFTs 1 manufactured so that the drain edge is formed (in the crystallization region) within about 0.8 μm from the crystal growth start position 7, or about 1.3 to 1.7 μm, about 2.3 to 3.6 μm, or about 4.2 to 5.0 μm away from the crystal growth start position 7; these regions are difficult to utilize.

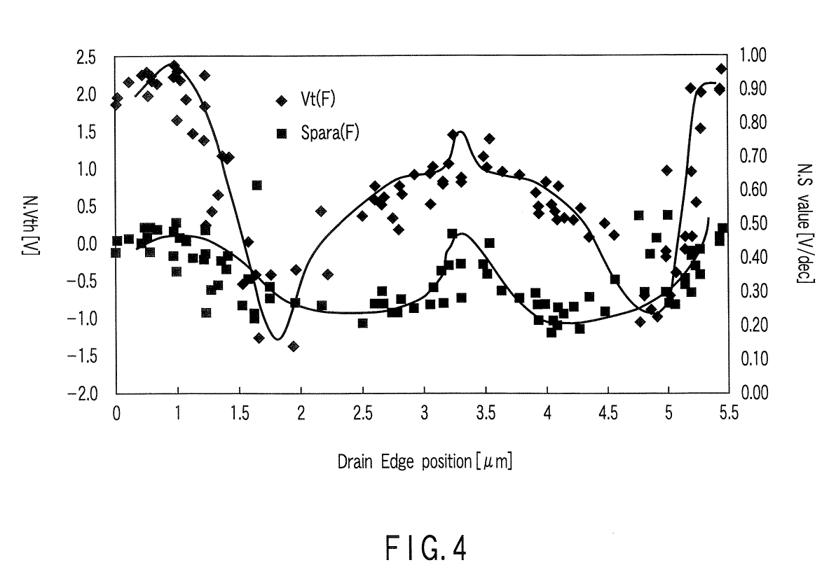

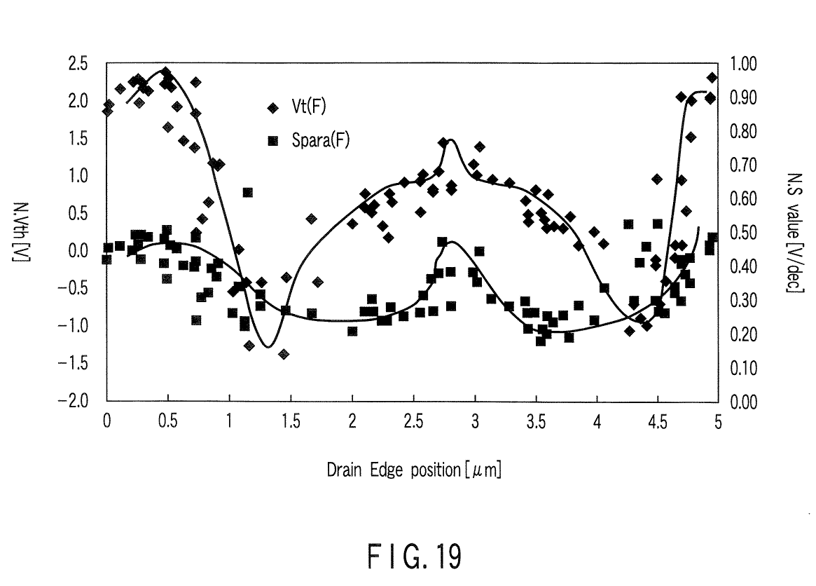

FIG. 4 and FIG. 19 are characteristic curve diagrams showing the relationship between both a threshold voltage Vth [V] and an S value [V/dec] and the drain edge in the n-channel TFTs 1 observed when TFT 1 is formed in the crystallization region; the S value is the inclination value of an on-off shift region. Vth is the switching voltage (threshold voltage) of TFT 1. The S value is a gate voltage that varies a drain current by one order of magnitude while keeping a drain voltage constant.

This embodiment, the length between the crystal growth start position 7 and the crystal growth end position 8 (crystallization region) is 2.5 μm in the TFT shown in FIG. 1. The crystallization region is defined on the basis of the pulse width of the reverse peak-like light intensity distribution. For example, a technique has been established which enables a crystallization region of 5 μm size to be mass-produced.

Threshold Voltage Vth

A relatively stable threshold voltage Vth, that is, the optimum characteristic, is offered by n-channel type TFTs 1 manufactured so that the drain edge is formed (in the crystallization region) about 2.4 to 3.3 μm or about 3.5 to 4.3 μm away from the crystal growth start position 7 as seen from FIG. 4.

In another embodiment, a relatively stable threshold voltage Vth, that is, the optimum characteristic, is offered by n-channel type TFTs 1 manufactured so that the drain edge is formed (in the crystallization region) about 1.8 to 2.6 μm or about 3.0 to 3.8 μm away from the crystal growth start position 7 as seen from FIG. 19.

S Value

The minimum S value, that is, the optimum characteristic, is offered by n-channel type TFTs 1 manufactured so that the drain edge is formed (in the crystallization region) about 1.7 to 3.0 μm or about 3.7 to 5.0 μm away from the crystal growth start position 7 as seen from FIG. 4.

In another embodiment, the minimum S value, that is, the optimum characteristic, is offered by n-channel type TFTs 1 manufactured so that the drain edge is formed (in the crystallization region) about 1.2 to 2.6 μm or about 3.0 to 4.5 μm away from the crystal growth start position 7 as seen from FIG. 19.

Characteristic of the Vth and S Value

The above results indicate that for the stabilization of the threshold voltage Vth as well as the S value in a crystallization region of 5 μm size, appropriate characteristics are offered by TFTs 1 manufactured so that the drain edge is formed (in the crystallization region) about 2.4 to 3.3 μm or about 3.0 to 4.0 μm away from the crystal growth start position 7. Moreover, the S value is excessively large in TFTs 1 manufactured so that the drain edge is formed within about 1.5 μm from the crystal growth start position 7 or about 3.2 to 3.7 μm or about 5.0 to 5.5 μm away from the crystal growth start position 7; these TFT 1 cannot be utilized.

In another embodiment, the above results indicate that for the stabilization of the threshold voltage Vth as well as the S value in a crystallization region of 5 μm size, appropriate characteristics are offered by TFTs 1 manufactured so that the drain edge is formed (in the crystallization region) about 1.8 to 2.6 μm or about 3.0 to 3.8 μm away from the crystal growth start position 7. Moreover, the S value is excessively large in TFTs 1 manufactured so that the drain edge is formed within about 1.5 μm from the crystal growth start position 7 or about 2.6 to 3.2 μm or about 4.5 to 5.6 μm away from the crystal growth start position 7; these TFT 1 cannot be utilized.

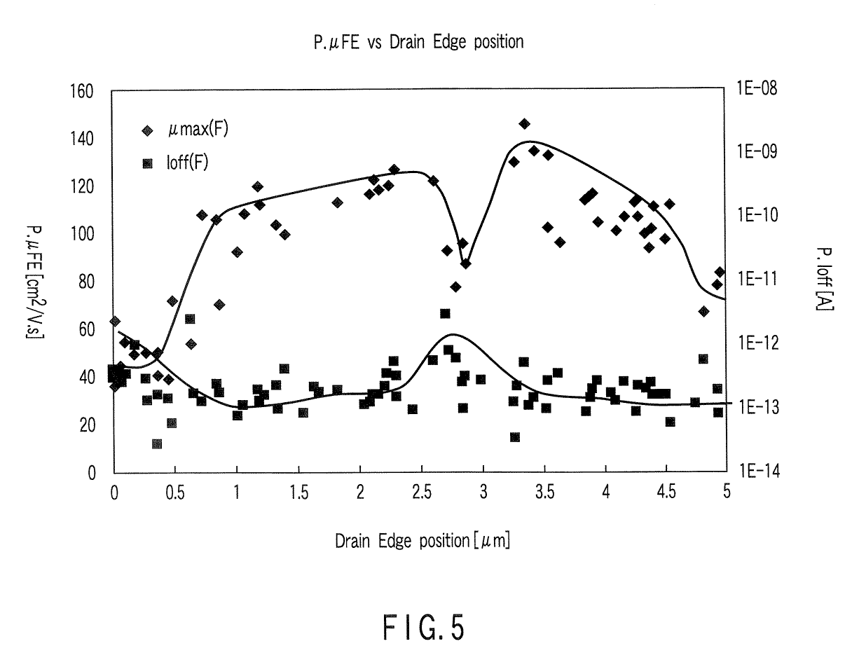

FIG. 5 is a characteristic curve diagram showing the relationship between both mobility and off current and the position of the drain edge in p-channel TFTs 1 observed when each TFT 1 is formed in the crystallization region 5 as described above. FIG. 5 shows the mobility μmax and off current Ioff characteristic, where a source-drain electrode voltage Vds=0.1 V and a source-gate electrode voltage Vgs=−5 V.

Mobility Characteristic

An appropriate mobility characteristic is offered by p-channel type TFTs 1 manufactured so that the drain edge is formed (in the crystallization region) about 0.7 to 2.6 μm or about 3.1 to 4.5 μm away from the crystal growth start position 7.

Offset Characteristic

The minimum, appropriate range of off current is exhibited by p-channel type TFTs 1 manufactured so that the drain edge is formed (in the crystallization region) about 0.7 to 2.5 μm or about 3.2 to 4.7 μm away from the crystal growth start position 7.

A larger off current is exhibited by TFTs 1 manufactured so that the drain edge is formed (in the crystallization region) within about 0.5 μm from the crystal growth start position 7 or about 2.6 to 3.1 μm away from the crystal growth start position 7; these regions are difficult to utilize.

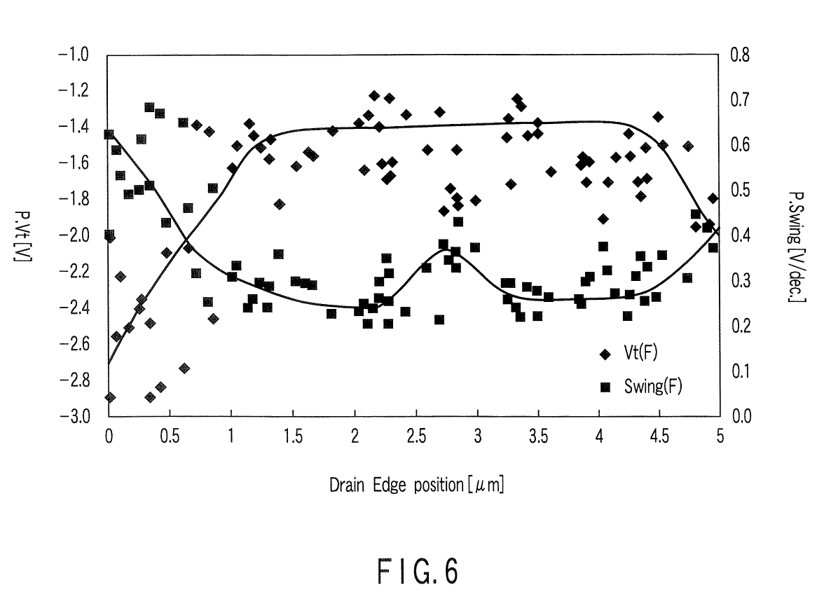

FIG. 6 is a characteristic curve diagram showing the relationship between both threshold voltage Vth and S value and the position of the drain edge in p-channel TFTs 1 observed when each TFT 1 is formed in the crystallized crystallization region as described above.

Threshold Voltage Vth

A relatively stable threshold voltage Vth of −1.5 V, that is, the optimum characteristic, is offered by p-channel type TFTs 1 manufactured so that the drain edge is formed in the crystallization region about 1.0 to 2.5 μm or about 3.5 to 4.7 μm away from the crystal growth start position 7.

On the other hand, the threshold voltage Vth lowers from −1.6 V to −2.7 V in p-channel type TFTs 1 manufactured so that the drain edge is formed in the crystallization region within about 1.0 μm from the crystal growth start position 7 or about 2.6 to 3.2 μm or about 4.6 to 5.0 μm away from the crystal growth start position 7; it is difficult to form a drain edge in these regions.

S Value

The minimum S value, that is, the optimum characteristic, is offered by TFTs 1 manufactured so that the drain edge is formed (in the crystallization region) about 1.0 to 2.5 μm or about 3.0 to 4.7 μm away from the crystal growth start position 7.

Characteristic of the Vth and S Value

The above results indicate that for the stabilization of the threshold voltage Vth as well as the S value in a crystallization region of 5 μm size, appropriate Vth and S value characteristics are offered by thin-film transistors manufactured so that the drain edge is formed about 1.0 to 2.5 μm or about 3.0 to 4.7 μm away from the crystal growth start position 7. On the other hand, a reduced threshold voltage VTh and a sharply increased S value are observed in TFTs 1 manufactured so that the drain edge is formed (in the crystallization region) within about 0.6 μm from the crystal growth start position 7 or about 4.8 to 5.0 μm away from the crystal growth start position 7; these regions are difficult to utilize. The above results indicate that for the stabilization of Vth as well as the S value and with a crystal of 5 μm size, TFT is effectively produced about 1.0 to 2.5 μm or about 3.0 to 4.5 μm away from the crystal growth start position 7.

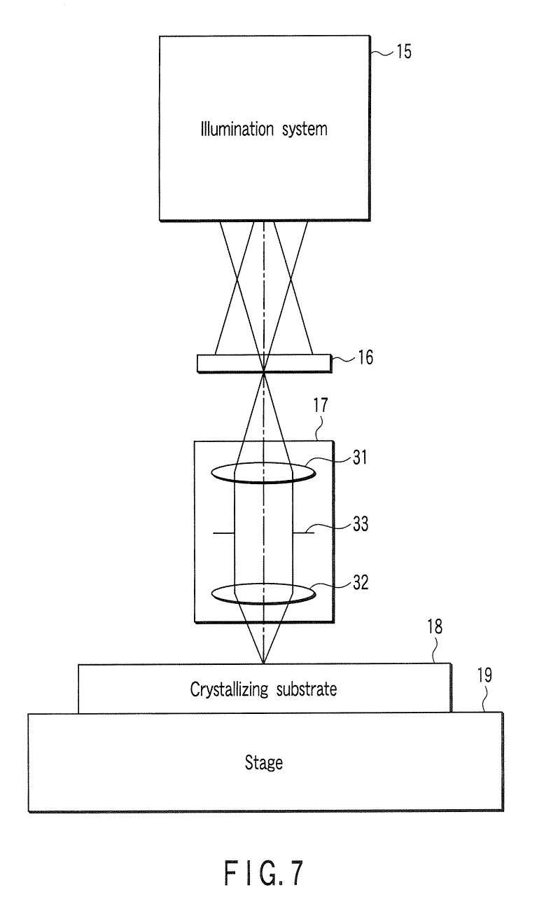

Now, an example of a crystallization apparatus will be described with reference to FIGS. 7 to 9. This crystallization apparatus forms a shape such that crystal growth progresses in the horizontal direction from the crystal growth start position 7, where a large number of fine crystal grains are present, with the crystal rising toward the crystal growth end position 8. The crystallization apparatus consists of an illumination system 15, a phase modulation element 16 provided on the optical axis of the illumination system 15, an image forming optical system 17 provided on the optical axis of the phase modulation element 16, and a stage 19 that supports a crystallizing substrate 18 provided on the optical axis of the image forming optical system 17.

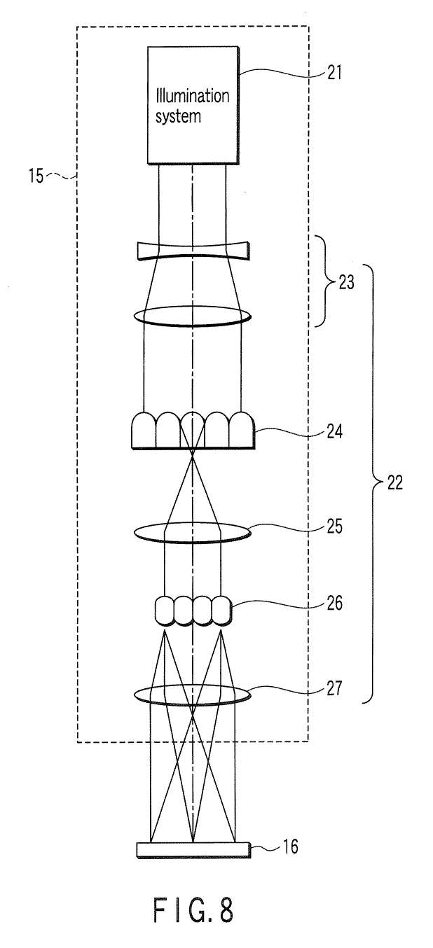

The illumination system 15 is the optical system shown in FIG. 8 and consists of, for example, a light source 21 and a homogenizer 22. The light source 21 may be a KrF excimer laser light source 21 that supplies light having a wavelength of for example, 248 nm. Alternatively, the light source 21 may be a an XeCl excimer laser light source that emits pulse light having a wavelength of 308 nm, a KrF excimer laser that emits pulse light having a wavelength of 248 nm, or an ArF excimer laser that emits pulse light having a wavelength of 193 nm. Alternatively, the light source 21 may be a YAG laser light source. Alternatively, the light source 21 may be another appropriate light source that outputs energy sufficient to melt the non-single-crystal semiconductor thin film, for example, the amorphous silicon film 4. A homogenizer 22 is provided on the optical axis of laser light emitted by the light source 21.

The homogenizer 22 homogenizes the light intensity of laser light emitted by the light source 21 as well as the incident angle of the light to the phase modulation element 16, in the cross section of the light flux. The homogenizer 22 has, for example, a beam expander 23, a first fly eye lens 24, a first condenser optical system 25, a second fly eye lens 26, and a second condenser optical system 27, all of which are provided on the optical axis of laser light from the light source.

Laser light from the light source 21 is incident on the illumination system 15 and is then enlarged via the beam expander 23. The light is then incident on the first fly eye lens 24. A plurality of light sources are formed on a rear focal plane of the first fly eye lens 24. A flux of light from the plurality of light sources illuminates an incident surface of the second fly eye lens 26 in a superimposing manner. As a result, more light sources are formed on the rear focal plane of the second fly eye lens 26 than on the rear focal plane of the first fly eye lens 24. A flux of light from the large number of light sources formed on the rear focal plane of the second fly eye lens 26 is incident on the phase modulation element 16 via the second condenser optical system 27. The light flux thus illuminates the phase modulation element 16 in a superimposing manner.

As a result, the first fly eye lens 24 and first condenser optical system 25 in the homogenizer 22 constitute a first homogenizer, which homogenizes the incident angle of laser light incident on the phase modulation element 16. The second fly eye lens 26 and second condenser optical system 27 constitute a second homogenizer, which homogenizes the light intensity of laser light from the first homogenizer at each position on the surface of the phase modulation element 16, the incident angle of the light having already been homogenized. The illumination system 22 thus forms laser light having an almost uniform light intensity distribution. The phase modulation element 16 is irradiated with this laser light.

The phase modulation element 16, that is, a phase shifter, modulates the phase of light emitted by the homogenizer 22. That is to say, the phase modulation element 16 is an optical element that emits laser beams having a reverse peak-like minimum light intensity distribution such as the one shown in FIG. 9(b), which is a partly enlarged view of a reverse peak-like minimum light intensity distribution. In this figure, the axis of abscissa indicates position (position on the irradiated surface), while the axis of ordinate indicates light intensity (energy).

The phase shifter 16 used as a phase modulation element can be formed by creating steps in a transparent member, for example, a quartz base material. The phase shifter 16 diffracts laser beams at the boundary between steps so that they interfere with each other, to apply a periodic spatial distribution to the laser light intensity. The phase shifter has a lateral phase difference of 180° around the boundary corresponding to a step portion x=0. In general, when the wavelength of laser light is defined as λ and a transparent medium with a refractive index n is formed on the transparent base material, the difference t in film thickness between the transparent medium and the transparent base material required to achieve a phase difference of 180° is given by t=λ/2(n−1). When the quartz base material has a refractive index of 1.46, since XeCl excimer laser light has a wavelength of 308 nm, a step of 334.8 nm size is required to achieve a phase difference of 180°. The step can be formed by, for example, selective etching.

Alternatively, a step portion can be formed by using an SiNx film as a transparent medium and depositing it by PECVD, LPCVD, or the like. In this case, when the SiNx film has a refractive index of 2.0, it may be deposited on the quartz base material to a thickness of 154 nm and then etched to form a step. The intensity of laser light having passed through the phase shifter with a 180° phase difference exhibits a periodic varying pattern.

In the present embodiment, a periodic phase mask has repeatedly and periodically formed steps. In the present embodiment, both the width of a phase sift pattern and the distance between patterns are, for example, 3 μm. The phase difference need not necessarily be 180° but has only to vary the intensity of laser light suitably for crystallization.

Laser light having its phase modulated by the phase modulation element 16 is incident on the crystallizing substrate 18 such as an amorphous silicon film via the image forming optical system 17, shown in FIG. 7. The image forming optical system 17 is placed so that the pattern surface of the phase modulation element 16 is optically conjugate to the crystallizing substrate 18. In other words, the height position of the stage 19 is corrected so as to set the crystallizing substrate 18 on a surface (image surface of the image forming optical system 17) optically conjugate to the pattern surface of the phase modulation element 16. The image forming optical system 17 comprises an aperture stop 33 between a positive lens group 31 and a positive lens group 32. The image forming optical system 17 may be an optical lens which projects an image from the phase modulation element 16, on the crystallizing substrate 18 without changing its scale or which reduces the scale to, for example, one-fifth.

The aperture stop 33 has a plurality of aperture stops including aperture portions (light transmission portions) with different sizes. These aperture stops 33 may be replaced with each other with respect to the optical path. Alternatively, each of the aperture stops 33 may have an iris stop that can continuously vary the aperture portion. In any case, the size of the aperture in the aperture stop 33 (or the image-side numerical aperture NA of the image forming optical system 4) is set so as to generate a required light intensity distribution on the semiconductor film on the crystallizing substrate 18. The image forming optical system may be a refractive or reflective optical system or a catadioptric optical system.

As shown in FIG. 9(a), the crystallizing substrate 18 is composed of the silicon oxide film 3 as an underlayer insulating film, the amorphous silicon film 4, and the cap film 35 sequentially formed on, for example, the glass substrate 2 for a liquid crystal display by chemical vapor phase deposition process (CVD process). The underlayer insulating film is formed of, for example, SiO₂ and has a film thickness of 500 to 1,000 nm. The underlayer insulating film 3 prevents the amorphous silicon film 4 from directly contacting the glass substrate to mix foreign matter such as Na deposited from the glass substrate 2, into the amorphous silicon film 4. The underlayer insulating film 3 also prevents a melting heat quantity from being transferred directly to the glass substrate 2 during crystallization of the amorphous silicon film 4. The underlayer insulating film 3 effectively stores melting heat to prevent temperature from lowering fast, thus contributing to forming a large-grain-size crystal.

The amorphous silicon film 4 is to be crystallized and has a film thickness of, for example, 30 to 250 nm. The cap film 35 stores heat generated when the amorphous silicon film 4 is melted during a crystallization process. This heat storage effect contributes to forming a large-grain-size crystallization region. The cap film 35 is an insulating film, for example, a silicon oxide film (SiO₂) and may have a film thickness of 100 to 400 nm, for example, 300 nm.

The crystallizing substrate 18 is automatically conveyed onto the stage 19 in such a crystallization apparatus as shown in FIG. 7. The crystallizing substrate 18 is then placed at a predetermined position and held by a vacuum or electrostatic chuck.

Now, the crystallization process will be described with reference to FIGS. 8 to 11. Pulse laser light emitted by the laser light source 21, shown in FIG. 8, is incident on the homogenizer 22, which homogenizes the intensity of the laser light and the incident angle of the light to the phase modulation element 16. In other words, the homogenizer 22 spreads the laser beam from the light source 21 in the horizontal direction to obtain a linear laser beam (which has, for example, a linear length of 200 mm). The homogenizer 22 further homogenizes the light intensity distribution. For example, a plurality of X-direction cylindrical lenses are arranged in a Y direction to form a plurality of light fluxes arranged in the Y direction, with other X-direction cylindrical lenses redistributing the light fluxes. Similarly, a plurality of Y-direction cylindrical lenses are arranged in the X direction to form a plurality of light fluxes arranged in the X direction, with other Y-direction cylindrical lenses redistributing the light fluxes.

The laser light may be, for example, XeCl excimer laser light with a wavelength of 308 nm. The duration of one shot pulse is, for example, 20 to 200 ns. The phase modulation element 16 is irradiated with pulse laser light under these conditions. Pulse laser beams entering the periodically formed phase modulation element 16 are diffracted at the step portion to interfere with one another. The phase modulation element 16 thus generates a periodically varying light intensity distribution like a reverse peak pattern such as the one shown in FIG. 9(b).

In the reverse peak pattern-like light intensity distribution, laser light intensity sufficient to melt the amorphous silicon film 4 is desirably output between a minimum light intensity portion L and a maximum light intensity portion P. Pulse laser light having passed through the phase modulation element 16 is incident on the amorphous silicon film 4 while being focused on the surface of the crystallizing substrate 18 by the image forming optical system 17.

The incident pulse laser light is almost transmitted through the cap film 35 and absorbed by the amorphous silicon film 4. As a result, the irradiated region of the amorphous silicon film 4 is heated and melted. The melting heat is stored by the presence of the cap film 35 and silicon oxide film 3.

When the irradiation with pulse laser light is blocked, the temperature of the irradiated region lowers. In this case, the heat stored in the cap film 35 and silicon oxide film 3 serves to lower the temperature very slowly. The temperature of the irradiated region lowers in accordance with the reverse peak pattern-like light intensity distribution generated by the phase modulation element 16. This causes crystal growth to sequentially progress in the horizontal direction from the minimum light intensity portion L to the maximum light intensity portion P.

In other words, a solidification position in a melted region in the irradiated region sequentially moves from low temperature side to high temperature side. That is to say, as shown in FIGS. 9(c) and 9(d), crystal growth progresses from the crystal growth start position 7 to the crystal growth end position 8. The crystal rises slightly in the vicinity of the crystal growth end position 8 in the irradiated region as shown in FIG. 9(d). FIG. 9(c) is a plan view illustrating the shape of the crystallization region 5 in the amorphous silicon film 4 obtained after the cap film 35 has been stripped off. FIG. 9(c) shows the form in which crystal growth progresses in the horizontal direction from the crystal growth start position 7 to the crystal growth end position 8.

FIG. 9(d) is a sectional view of FIG. 9(c). As shown in FIG. 9(d), the film thickness of the semiconductor thin film 4a increases from the crystal growth start position 7 toward the crystal growth end position 8. The crystal has an inclined surface having a peak at the crystal growth end position 8. Thus, FIG. 9(d) shows a cross section of the angled crystal. FIG. 9(d) also shows a plurality of reverse peak-like light intensity distributions as shown in FIG. 9(b). A single reverse peak-like light intensity distribution pattern results in a film thickness distribution with a pair of angled changes and only a pair of raised portions.

The crystallization process with pulse laser light is thus finished. The crystallization region subjected to crystal growth is large enough to house one or more functional elements. FIGS. 9(b), 9(c), and 9(D) show their mutual relationships using dotted lines. Specifically, in FIGS. 9(b), 9(c), and 9(D), crystal growth starts in the reverse peak portion L of the reverse peak-like light intensity distribution (crystal growth start position 7). The crystal growth ends in a positive peak portion P (crystal growth end position 8). FIG. 9(d) shows that the single crystal silicon film thickness sequentially increases from the crystal growth start position 7 to the crystal growth end position 8, with the crystal rising in the vicinity of the end position 8.

The crystallization apparatus 20, shown in FIG. 7, is controlled in accordance with a program pre-stored in a control device (not shown). Specifically, the crystallization apparatus 20 is controlled so that the crystallization region in the amorphous silicon film 4 is automatically irradiated with pulse laser light. To move to the next crystallization region, for example, the stage 19 can be moved to select an irradiated position. Of course, the crystallization position can be selected by moving the crystallizing substrate 18 and the light source 21 relative to each other.

Once the crystallizing region is selected and alignment is completed, the next pulse laser light is emitted. Repeating such a laser light shot enables the crystallizing substrate 18 to be crystallized over a wide range. The crystallization process is thus executed on the entire substrate. The amorphous silicon film 4 in which the crystallization region is formed as shown in FIG. 9(d) is called the semiconductor thin film 4a.

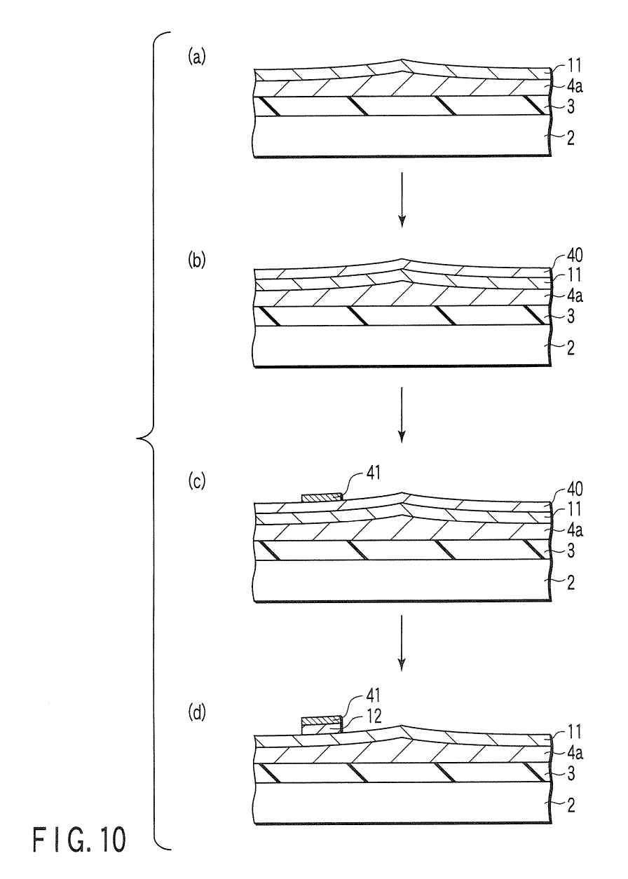

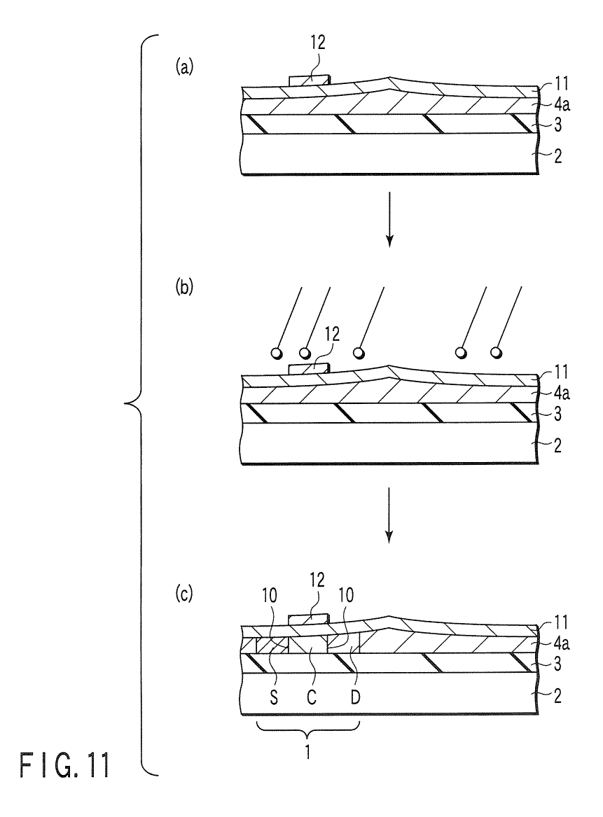

Now, with reference to FIGS. 10 and 11, description will be given of an example of a part of the TFT manufacture process which follows step-8, shown in FIG. 2, the part being executed on the crystallized substrate. The same components as those in FIGS. 1 to 9 are denoted by the same reference numerals and their detailed description is omitted.

An SiO₂ film, the cap film 35, has been deposited on the surface of the crystallized substrate. The SiO₂ film can also be used as a gate insulating film of TFT. However, if foreign matter from the amorphous silicon film 4 may be mixed into the SiO₂ film during the crystallization process as a result of abrasion, the SiO₂ film is preferably etched off. In the present example, the SiO₂ is removed.

As shown in FIG. 10(a), the gate insulating film 11, for example, an SiO₂ film, is deposited on the semiconductor thin film 4a, located on the surface of the substrate from which the cap film 35 has been removed. The gate insulating film 11 is formed by, for example, the LP-CVD process. A silicon oxide film of thickness 80 nm is deposited on the semiconductor thin film 4a. LP-CVD is carried out under conditions including, for example, a substrate temperature of 500° C. and a deposition time of 45 minutes.

The gate electrode 12 is then formed. Specifically, as shown in FIG. 10(b), a gate electrode layer, for example, an aluminum layer 40, is deposited on the gate insulating film 11. The aluminum layer 40 is deposited on the silicon oxide film (SiO₂ film) of the gate insulating film 11 to a thickness of, for example, 100 nm by, for example, sputtering. The sputtering conditions include, for example, a substrate temperature of 100° C. and a deposition time of 10 minutes.

The aluminum layer 40 is selectively etched to form a gate electrode 12 at a predetermined position. To achieve this, a resist pattern 41 is formed on the aluminum layer 40 by applying a resist film to the aluminum layer 40. The resist film is selectively exposed using a photo mask. The resist film is removed with a mask region for a gate electrode left to form a resist pattern 41 as shown in FIG. 10(c). In this case, the position of the resist pattern 41 is important, which is used to form a gate electrode 12. The resist pattern 41 is formed in the crystallization region at a position that does not correspond to the vicinity of the crystal growth start position 7.

The aluminum layer 40 is then removed using the resist pattern 41 as a mask. For example, a dry etching process is executed to form a gate electrode 12 as shown in FIG. 10(d). The dry etching process uses, for example, BCl₃ or CH₄ as an etching gas. Subsequently, as shown in FIG. 11(e), the resist pattern 41 on the gate electrode 12 is removed.

Then, as shown in FIG. 11(f), impurities are doped into the semiconductor thin film 4a using the gate electrode 12 as a mask. As the impurities, phosphorous ions are implanted into the semiconductor thin film 4a if TFT 1 of the present invention is of the n-channel type. Boron ions are implanted into the semiconductor thin film 4a if TFT 1 of the present invention is of the p-channel type. For example, a logic circuit such as a CMOS inverter is composed of a combination of an n-channel type TFT and a p-channel type TFT. Thus, ion implantation for forming one of an n- and p-channel type TFTs is carried out with the semiconductor thin film 4a in the other TFT covered using a mask such as a resist which inhibits unwanted ion implantation.

After the ions are implanted into the n- and p-channel type TFTs, an anneal process is executed to activate the impurities such as phosphorous or boron which have been implanted into the semiconductor thin film 4a. The anneal process is executed by a 3-hour thermal process at a substrate temperature of, for example, 600°° C. in a nitrogen atmosphere. As a result, as shown in FIG. 11(g), the source S and drain D regions both having a high concentration of impurities are formed in the semiconductor thin film 4a on the opposite sides of the gate electrode 12.

As a result, the side edge 10 of the source S or drain D region is formed in the vicinity of the crystal growth end position 8 as shown in FIG. 1.

An interlayer insulating film (not shown) is then formed on the gate insulating film 11 and gate electrode 12. A well-known process is used to form a source electrode, a drain electrode, a gate electrode (not shown), and the like via through-holes (not shown) formed in the interlayer insulating film. Such a method can be used to form TFT 1.

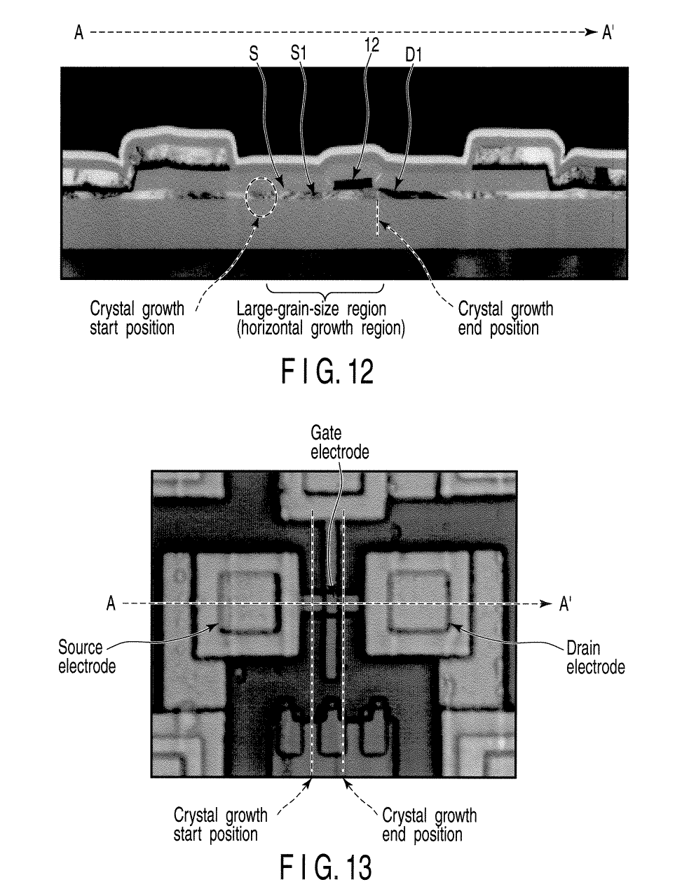

FIG. 12 shows a microscopic photograph of sectional structure of TFT 1 manufactured as described above. The side edge 10 of the drain region D is provided in the vicinity of the crystal growth end position 8 in the crystallization region. The side edge 10 is in contact with the channel region C formed under the gate electrode 12. FIG. 12 also shows that lamination defects S1 and D1 have occurred in the source S and drain D regions in TFT and run from a deeper portion toward a shallower portion of the semiconductor thin film 4a. FIG. 12 further shows that the gate electrode 12 is inclined.

FIG. 13 is a plan view of FIG. 12. FIG. 13 shows that the side edge 10 of the drain region D which is adjacent to the channel region C is provided in the vicinity of the crystal growth end position 8.

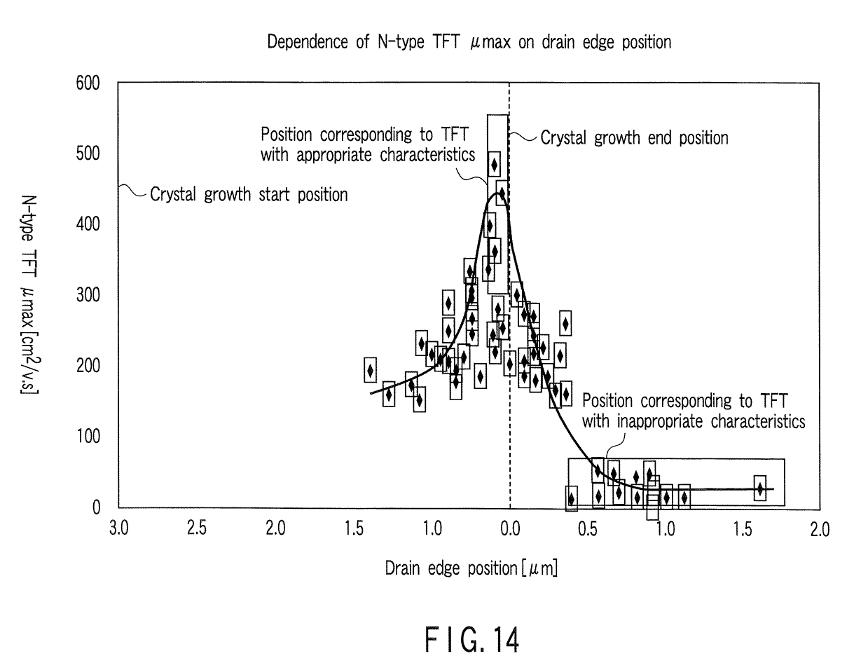

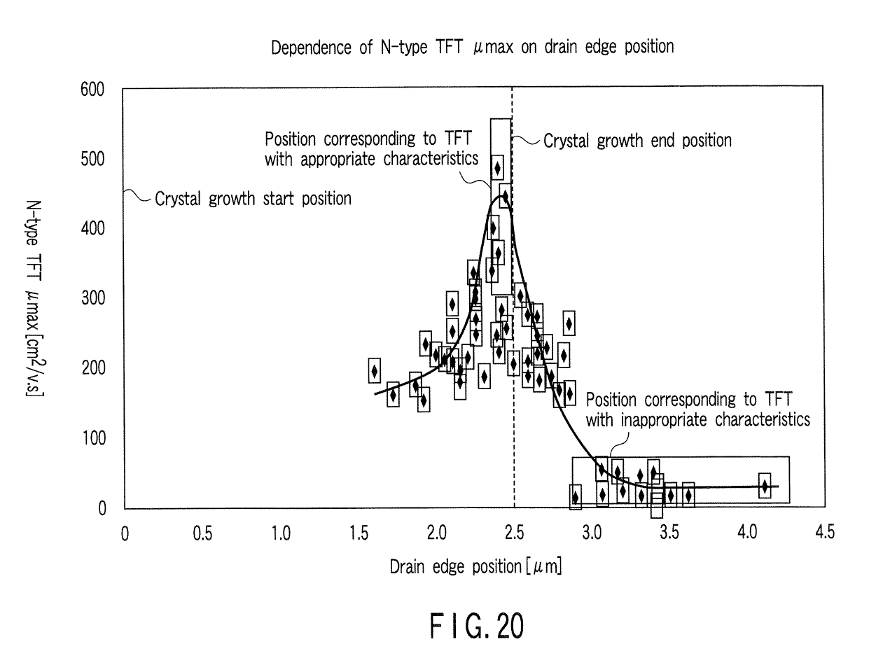

FIG. 14 and FIG. 20 show the relationship between the position of the drain side edge 10 of an n-type TFT formed on a glass substrate, with respect to the crystal growth end position 8, and the mobility of electrons and holes in the n-type TFT. The drain side edge 10 is formed in the vicinity of the crystal growth end position 8.

As shown in FIG. 14, TFT 1 in which the edge 10 of the drain region D located adjacent to the channel region C is formed within 1.5 μm from the crystal growth end position 8 exhibits a mobility of 150 cm²/v.s. In particular, TFT 1 in which the edge 10 of the drain region D located adjacent to the channel region C is formed within 0.05 to 0.2 μm from the crystal growth end position 8 exhibits a high mobility of 300 cm²/v.s.

FIG. 14 is a plot of mobility characteristics of a large number of n-type TFTs. These mobility characteristics are offered by n-type TFTs in which the drain edge (channel region side edge of the drain region D) is formed within 1.5 μm from the crystal growth end position 8. The characteristics plotted with rectangles indicate the mobility characteristics of n-type TFTs in which the source edge (channel region side edge of the source region S) is formed within 1.5 μm from the crystal growth end position 8. The mobility characteristics are determined from a characteristic curve diagram showing the gate voltage (axis of abscissa) vs. the drain current (axis of ordinate). When the edge in TFT is formed within 1.5 μm from the crystal growth end position 8, the characteristic offered is almost the same regardless of whether the edge belongs to the drain or source region.

In FIG. 14, data plotted far away from the crystal growth end position 8 (in the vicinity of the next crystallization region end position 8) indicates the characteristic of TFTs in which the channel region is formed across the crystal growth end position 8. The characteristics shown in FIG. 14 are offered by the n-type TFTs but can be obtained from p-type TFTs. Moreover, in TFT 1 in the present example, a current flows parallel to the direction of the crystal growth, that is, the horizontal direction. It is optimum to pass current in the direction of crystal growth.

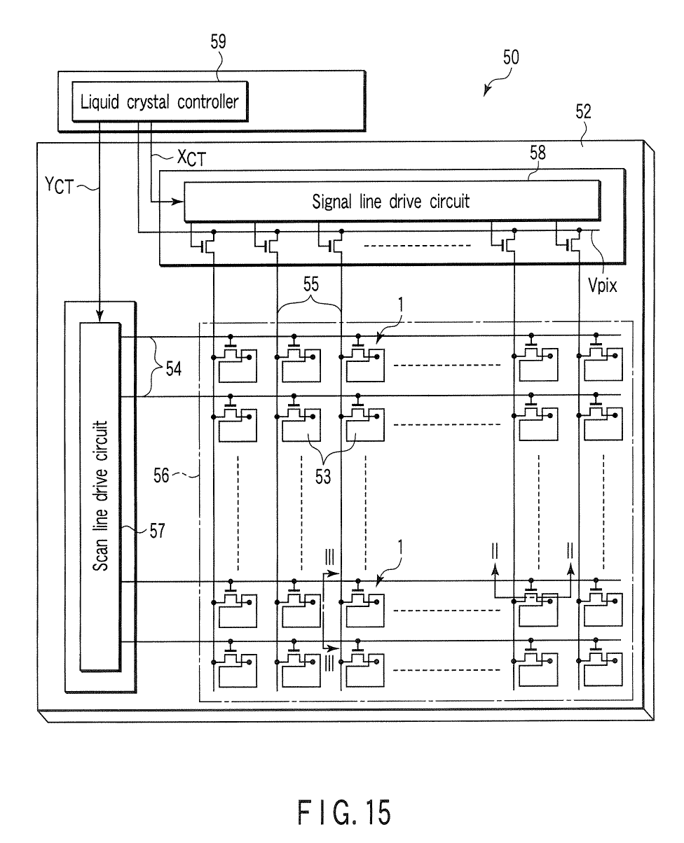

Now, with reference to FIG. 15, description will be given of an example in which TFTs according to the present invention are applied to a transistor circuit in a display, for example, a liquid crystal display. The same components as those in FIGS. 1 to 14 are denoted by the same reference numerals and their description is omitted.

FIG. 15 shows an example of a display section of an active matrix type liquid crystal display 50 comprising a transparent substrate 52, pixel electrodes 53, scan lines 54, signal lines 55, counter electrodes 56, TFTs 1, a scan line drive circuit 57, a signal line drive circuit 58, and a liquid crystal controller 59.

The above thin-film transistors constitute a peripheral circuit section including the scan line drive circuit 57 and signal line drive circuit 58 and which needs to operate at high speed. This display can implement a system display including active elements for the peripheral circuit section, a memory circuit section, and the like.

The TFT 1 according to the present invention are formed to have such a structure as described with reference to FIG. 1 and constitute the peripheral circuit section including the scan line drive circuit 57 and signal line drive circuit 58 and which needs to operate at high speed. The peripheral circuit section including the scan line drive circuit 57 and signal line drive circuit 58 is desirably composed of TFTs in which the source edge of the source region S or the drain edge of the drain region D is formed within 0.05 to 0.2 μm from the crystal growth end position 8. The formation of such TFTs enables the peripheral circuits to be composed of TFTs with excellent characteristics including a mobility (μmax) of at least 300 cm²/Vg·s.

A thus manufactured display can implement a system display including active elements for the peripheral circuit section, a memory circuit section, and the like. This display is also effective in reducing the size and weight.

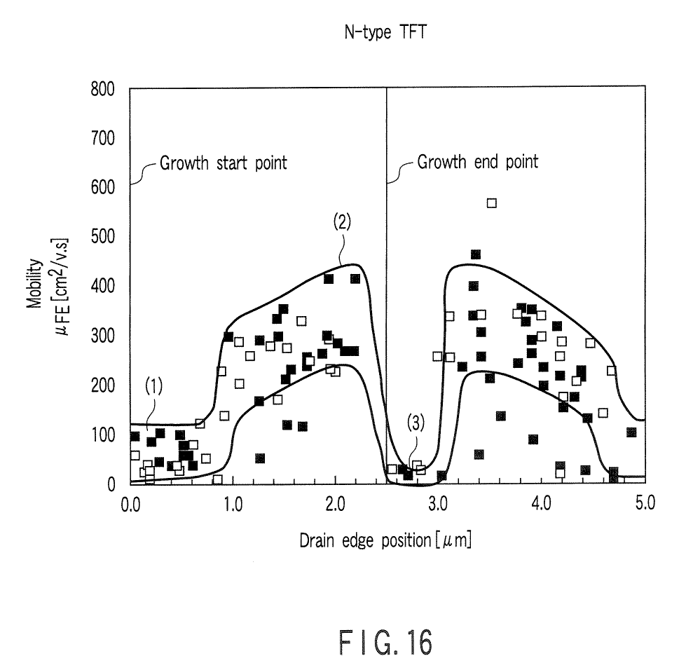

Now, another example of TFTs will be described with reference to FIGS. 16 to 18. FIG. 16 is a diagram showing the mobility characteristics of a large number of n-channel type TFTs manufactured so that the position (drain edge position) of the portion of the drain region which joins to the channel region is varied between the crystal growth start position and the crystal growth end position. These TFTs have the same structure as that of TFT shown in FIG. 1. However, instead of the glass substrate 2, a P-type silicon wafer substrate of thickness 625 μm is used. The channel region has a film thickness of 200 nm.

For the n-channel type TFTs shown in FIG. 16, the mobility starts to increase when the drain edge is positioned about 0.8 μm away from the crystal growth start position and continuously increases while the drain edge is positioned between 0.8 and 2.3 μm from the crystal growth start position. In particular, TFTs in which the drain edge is formed about 1.6 μm from the crystal growth start position exhibit a mobility of 760 cm/v.s. These characteristics are offered when the length between the crystal growth start position 7 and crystal growth end position 8 shown in FIG. 9 is 2.5 μm. The length between the crystal growth start position 7 and the crystal growth end position 8 is determined by the pulse width of the reverse peak-like light intensity distribution in FIG. 9(b). In connection with the length between the crystal growth start position 7 and the crystal growth end position 8, a technique has been established which enables, for example, a crystallization region of 5 μm size to be mass produced.

It has been confirmed that when the length between the crystal growth start position 7 and the crystal growth end position 8 is 5 μm, the values for the drain edge position corresponding to the optimum mobility are twice as large as those in the data shown in FIG. 16. Specifically, for such n-channel type TFTs, the mobility starts to increase when the drain edge is positioned about 1.6 μm away from the crystal growth start position and continuously increases while the drain edge is positioned between 1.6 and 4.6 μm from the crystal growth start position.

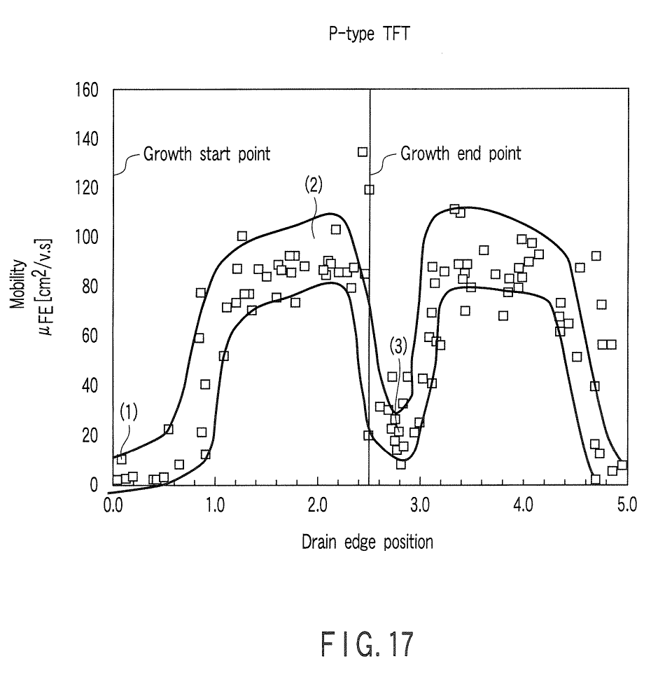

An example of the mobility characteristic vs. the drain edge position in p-channel type TFT is shown in FIG. 17. As shown in this figure, the mobility starts to increase when the drain edge is positioned about 1 μm away from the crystal growth start position and continuously increases while the drain edge is positioned between 1 and 2.3 μm from the crystal growth start position. As is the case with FIG. 16, these characteristics are offered when the length between the crystal growth start position 7 and crystal growth end position 8 is 2.5 μm.

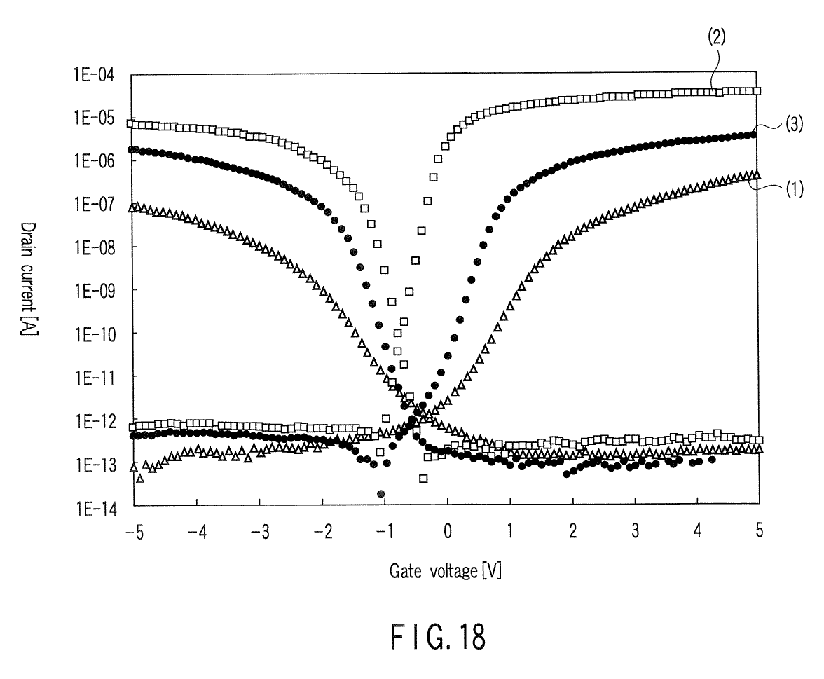

FIG. 18 shows a characteristic curve diagram showing the drain current vs. the gate voltage in TFTs in which the drain edge is formed (1) in the vicinity of the crystal growth start position, (2) at the optimum position for the mobility, or (3) in the vicinity of the crystal growth end position. As shown in FIG. 18, the optimum characteristic is offered at the optimum position for the mobility (2). FIGS. 16 to 18 share the relationship among the position (1) in the vicinity of the crystal growth start position and the position (2) at the optimum position for the mobility and the position (3) in the vicinity of the crystal growth end position.

The thin-film transistors shown in FIG. 1 can constitute the thin-film transistors 1 in each circuit and a memory, a capacitor, a resistor, and the like which are composed of thin-film transistors as required. In other words, in the present specification, the term “thin-film transistor” includes what can be composed of the thin-film transistors shown in FIG. 1 apart from its functions.

The thin-film transistor 26 thus manufactured is applicable to a drive circuit for a liquid crystal display or an EL (Electro Luminescence) display, or an integrated circuit for a memory (SRAM or DRAM) or CPU in each pixel circuit.

As described above, the above embodiments provide TFTs having a high electron or hole mobility. TFTs exhibiting such a high mobility are applicable to the peripheral circuit section including the scan line drive circuit 57 and the signal line drive circuit 58.

The present invention provides TFT offering the optimum transistor characteristics, a method for manufacturing the TFT, and a display using the TFT.

The several embodiments of the present invention have been illustrated and described. The embodiments of the present invention described in the present specification are only illustrative and can obviously be varied without departing from the scope of the present invention.

What is claimed is:

1. A thin-film transistor having a source region, a channel region, and a drain region in a semiconductor thin film having a crystallization region with a crystal grown in a horizontal direction, the thin-film transistor having a gate insulating film and a gate electrode over the channel region,
wherein a channel region side edge of the drain or source region is provided in the crystallization region at a position which does not correspond to a vicinity of a crystal growth start position or a vertical direction growth start position.

2. A thin-film transistor having a source region, a channel region, and a drain region in a semiconductor thin film having a crystallization region with a crystal grown in a horizontal direction, the thin-film transistor having a gate insulating film and a gate electrode over the channel region, wherein a channel region side edge of the drain or source region is provided in the crystallization region at least 1.0 μm away from a vertical direction growth start position.

3. A thin-film transistor having a source region, a channel region, and a drain region in a semiconductor thin film having a crystallization region with a crystal grown in a horizontal direction, the crystallization region having an inclined surface which rises toward a crystal growth end, the thin-film transistor having a gate insulating film and a gate electrode over the channel region,
wherein a channel region side edge of the drain or source region is provided in the crystallization region at least 1.0 μm away from a vertical direction growth start position.

4. The thin-film transistor according to claim 1, wherein the crystallization region is a single-crystal region formed by irradiating a non-single-crystal semiconductor film with laser light corresponding to pulse laser light made by a phase shifter via a homogenizer to have a reverse peak-like light intensity distribution.

5. The thin-film transistor according to claim 2, wherein the crystallization region is a single-crystal region formed by irradiating a non-single-crystal semiconductor film with laser light corresponding to pulse laser light made by a phase shifter via a homogenizer to have a reverse peak-like light intensity distribution.

6. The thin-film transistor according to claim 3, wherein the crystallization region is a single-crystal region formed by irradiating a non-single-crystal semiconductor film with laser light corresponding to pulse laser light made by a phase shifter via a homogenizer to have a reverse peak-like light intensity distribution.

7. A method for manufacturing a thin-film transistor, the method comprising:
a step of irradiating a non-single-crystal semiconductor film with laser light having a reverse peak-like light intensity distribution to crystallize an irradiated region to form a crystallization region; and
a step of forming a thin-film transistor so that a side edge of the drain or source region which is adjacent to the channel region is positioned in the crystallization region at least 1.0 μm away from a crystal growth start position or a vertical growth start position in the crystallization region.

8. A display having the thin-film transistor according to claim 1 provided in a peripheral circuit section including a signal and scan line drive circuits which needs to operate at high speed.

9. A display having the thin-film transistor according to claim 2 provided in a peripheral circuit section including a signal and scan line drive circuits which needs to operate at high speed.

10. A display having the thin-film transistor according to claim 3 provided in a peripheral circuit section including a signal and scan line drive circuits which needs to operate at high speed.
